(19) United States
(12) Patent Application Publication
(10) Pub. No.: US 2014/0197398 A1
(43) Pub. Date: Jul. 17, 2014

(54) DOPANT INJECTION LAYERS

(71) Applicants: John Devin MacKenzie, Lafayette, CA (US); Eric Jones, Santa Cruz, CA (US); Yuko Nakazawa, Santa Cruz, CA (US)

(72) Inventors: John Devin MacKenzie, Lafayette, CA (US); Eric Jones, Santa Cruz, CA (US); Yuko Nakazawa, Santa Cruz, CA (US)

(73) Assignee: SUMITOMO CHEMICAL CO., LTD., Tokyo (JP)

(21) Appl. No.: 14/232,995

(22) PCT Filed: Aug. 2, 2012
(86) PCT No.: PCT/US2012/049397

§ 371 Date: Mar. 26, 2014

Related U.S. Application Data
(60) Provisional application No. 61/514,425, filed on Aug. 2, 2011.

(51) Int. Cl. H01L 51/50

(52) U.S. Cl. CPC H01L 51/5088
USPC 257/40

(57) ABSTRACT

The present invention uses an isopotential source layer for an electronic device, wherein the source layer provides ions of charge to be preferentially injected into an active layer of the electronic device, such that a charge of the injected ions has the same sign as the sign of a relative bias applied to the isopotential source layer. The source layer may comprise a composite ionic dopant injection layer having at least one component that has a relatively high diffusivity for ions. The composite ionic dopant injection layer may comprise metallic conductive particles and an ion supporting matrix. The composite ionic dopant injection layer may also comprise a continuous metallic conductive network and an ion supporting matrix. The metallic network comprises metallic nanowires or conductive nanotubes. The ion supporting matrix may comprise a conductive polymer.

### CROSS-REFERENCE TO RELATED APPLICATION

This application claims priority to U.S. Provisional Application. Ser. No. 61/514,425 filed Aug. 2, 2011, entitled “Dopant Injection Layers”, the entirety of which is incorporated herein by reference.

### FIELD OF THE INVENTION

This invention relates to use of source layers for injecting ions for improved performance in electronic devices.

### BACKGROUND

Light-emitting electrochemical cells utilize mobile ions to narrow the barriers to injection of electrons and holes into a conjugated polymer-based light emitting device. U.S. Pat. No. 5,682,043 to Pei et al. shows such an example device. These devices do not require using low work function metals as a cathode. These devices can achieve reasonably high device efficiencies and low operating voltages. However, as described in U.S. Pat. No. 5,682,043, the turn-on kinetics of these devices are relatively slow. Furthermore, the devices are inherently charge-neutral with equal cation and anion concentrations, but, the presence of equal cation and anion concentrations may not be optimal.

Use of multilayer devices with charge injection-enhancing layers is a potential means for improving device efficiency and lifetime. Some references have described multilayer devices consisting of conducting polymer hole injection layers for the improvement of polymer and small molecule organic light emitting diodes. In a conventional polymer OLED multilayer device structure, polymer-doped conjugated organic thin films have been used as hole injection layers. However, in these cases, the conducting polymer, formed by a conjugated species (poly(3,4-ethylenedioxythiophene)—PEDT or PEDOT), which is doped with polystyrene sulfonic acid (PSS), does not intentionally contain mobile ions. In fact, the doping polymer, PSS typically has much higher molecular weight than the conjugated segments, forms the majority of the solid film, and are essentially immobile as compared to a mobile dopant. It is also interesting to note that the ratio of conjugated PEDOT to PSS is typically relatively low. In the range of interest for many applications of PEDOT:PSS from antistatic coatings to discrete OLEDs and passive matrix OLEDs which require special measures to ensure electrical isolation and therefore low lateral PEDOT:PSS conductivities, the PSS content is higher than the PEDOT content and the conductivity decreases with increasing PSS content. Higher conductivity grades of PEDOT:PSS are not typically sought after for conventional OLED devices.

PEDOT:PSS has been used less for light emitting electrochemical cells, known as LECs. LEC operating principle includes using mobile ionic dopants in the light emitting layer producing doped interfaces at the anode. This reduces the need for a hole injection enhancement layer, such as PEDOT:PSS, as the LEC-doped interfaces already serve this purpose. Note that doped PEDOT:PSS layers do absorb some of the light propagating through these layers from the active layer of the device. This decreases the external efficiency and therefore makes typical PEDOT:PSS undesirable, unless it is necessary for other reasons. Based on known art and a simple consideration of the LEC model, one would assume that doped conjugated polymer injection layers are not advantageous for inclusion in LECs and that high doping levels are also not advantageous due to high absorption losses and leakage currents. Furthermore, in conventional OLEDs the presence of ionic species, and in particular a mobile ion that might drift or diffuse into the active layer of the device is generally thought of as undesirable as these impurities can lead to efficiency losses and device degradation.

Recently, another type of doping multilayer has been proposed for organic light emitting device structures. In this case multilayers are proposed such that inherent drift mobility rates control the flow of dopants in LEC-like devices to create advantageous effects. In the extreme case, dopant counter-ions may even be fixed by covalent bonding. Also, the use of ion receptors to fix ions supplied from a counter-ion layer has been proposed in U.S. Pat. No. 7,868,537 to Meijer, et al., titled, “Polymer light-emitting diode with an ion receptor layer.” U.S. Pat. No. 7,868,537 also includes an exemplification and description of a device using a PEDOT:PSS layer as a source of mobile cations which could flow under forward bias towards a cation receptor. However, U.S. Pat. No. 7,868,537 attributes a cation source in PEDOT:PSS as Na+ which is not intentionally present in significant quantities and is commonly attributed as a cause of bias stress degradation in devices. Furthermore, U.S. Pat. No. 7,868,537 attributes the immobilizaiton of the anion to its polymeric nature.

U.S. Pat. No. 7,868,537 does not describe the fact that the metallic nature of PEDOT:PSS, in which a zero electric field would suppress ion motion within the PEDOT:PSS and at the PEDOT:PSS interface would preferentially inject only cations under a positive bias on the PEDOT:PSS, regardless of the anion size. Within a conducting injection layer (such as PEDOT:PSS) with a high carrier concentration, cation and anion redistribution would be driven by diffusion. In forward bias (positive PEDOT:PSS), injection of mobile cations would rapidly deplete the region within the PEDOT:PSS at the active layer interface. Without a significant amount of mobile ions distributed throughout the PEDOT:PSS, which could diffuse to the interfacial region and sustain a supply of cations, the dopant injection effect would be suppressed. These dopants would have to be introduced as an intentional, extrinsic dopant, as described later in this application.

### SUMMARY

The present invention uses an isopotential source layer for an electronic device, wherein the source layer provides ions of charge to be preferentially injected into an active layer of the electronic device, such that a charge of the injected ions has the same sign as the sign of a relative bias applied to the isopotential source layer. The source layer may comprise a composite ionic dopant injection layer having at least one component that has a relatively high diffusivity for ions. The composite ionic dopant injection layer may comprise metallic conductive particles and an ion supporting matrix. The composite ionic dopant injection layer may also comprise a continuous metallic conductive network and an ion supporting matrix. The metallic network comprises metallic nanowires or conductive nanotubes. The ion supporting matrix may comprise a conductive polymer.

In an embodiment, the device may comprise a transparent anode, a conducting polymer layer in contact with the transparent anode with additional mobile ion dopants adjacent to the active layer.

In another embodiment, the device may comprise a transparent cathode and a doped anode, the doped anode which being a composite of an electrically continuous network of metallic elements and an ion supporting matrix.

These and other embodiments and aspects of the present invention would be apparent to persons skilled in the art in view of the detailed description and the enclosed drawings.

### BRIEF DESCRIPTION OF THE DRAWINGS

FIGS. 1A-1B show initial ‘turn-on’ data from constant current testing of printed devices showing the impact of cathodes doped with a certain ‘salty’ Ag formulation on constant current device luminance and voltage performance over time versus an undoped cathode control.

FIG. 2 shows EL images taken immediately after fabrication of control (undoped devices with cathodes using standard Ag formulation) and doped cathode devices using two different ‘salty’ Ag formulations. All the devices comprise screen printed LEPs. The top row images are from two devices using standard Ag formulation 10-243-1Ag. The middle row images are from two devices using salty Ag formulation 10-243-1-ion1. The bottom row images are from two devices using salty Ag formulation 10-243-1-ion2, which is twice as heavily doped than 10-243-1-ion1, as described in more detail later. The poor efficiency of the doped devices and the poorer efficiency in the more heavily doped cathodes are apparent in the pictures as compared to the controls.

FIG. 3 illustrates graphical representation of an experimental data set, normalized and exponentially fitted to the control data for each set. The peak value in the fit indicates a doping level of ˜17% BMP/PEDOT:PSS solids by weight.

FIGS. 4A-4C show dopant concentration (the graphs in the top row) and ion distributions (the device schematics in the bottom row) for the case of a uniformly, mobile ion-doped light emitting device (LEC-type) with equal anion and cation mobilities at different points of time, as discussed further below. In this homogeneous doping situation, equal diffusivity of all ions is assumed. In the device schematics, one electrode is shown to be smooth ITO (element 402), and the other electrode 404 is shown to be granular or particulate. However, persons skilled in the art will understand that the specific material, properties, and configuration of the electrode can be modified within the scope of this invention to suit a desired situation. The light emitting material 406 between the two electrodes has the positive and negative ions.

FIGS. 4A-4C show the expected progress of the dopant distributions over time. Specifically, the three cases from left to right are: before bias (FIG. 4A), initially after bias (FIG. 4B), and after significant time under bias (FIG. 4C). Reduction in doping near the cathode is noted due to leaching of dopant into the cathode.

FIGS. 5A-5C illustrate ion distributions for the case of a device with an active layer with a higher doping concentration layer adjacent to the cathode and a lower doping concentration layer near the anode, with equal anion and cation mobilities showing the expected progress of the dopant distributions over time. In one embodiment, the heavily doped layer adjacent to the anode may be twice as heavily doped compared to the relatively lightly doped layer adjacent to the cathode. There may be multiple (two or more) discrete layers between the cathode and the anode, each having their own doping concentration level. Graded concentration difference is possible too. Specifically in FIG. 5, the three cases from left to right are: before bias (FIG. 5A), initially after bias (FIG. 5B), and after significant time under bias (FIG. 5C). Note that the device is initially charge neutral with respect to ions prior to biasing. As in the case of FIGS. 4A-4C, equal diffusivity of all ions is assumed.

FIGS. 6A-6C illustrate ion distributions for the case of a device with homogenuously doped (as deposited) active layer with a doped cathode layer with equal anion and cation mobilities showing the expected progress of the dopant distributions over time. Specifically, the three cases from left to right are: before bias (FIG. 6A), initially after bias (FIG. 6B), and after significant time under bias (FIG. 6C). A small increase in near cathode doping may be expected due to diffusion and intermixing from the doped cathode. As in the case of FIGS. 4A-4C and 5A-5C, equal diffusivity of all ions is assumed.

FIGS. 7A-7C illustrate ion distributions for the case of a device with homogenuously doped (as deposited) active layer with a doped conductive anode dopant injection layer with equal anion and cation mobilities showing the expected progress of the dopant distributions over time. Specifically, the three cases from left to right are: before bias (FIG. 7A), initially after bias (FIG. 7B), and after significant time under bias (FIG. 7C). A small increase in near anode doping may be expected due to diffusion and intermixing from the doped layer. Over time this creates a high cation concentration in the active layer of the device improving hole balance in electron injection-limited devices while minimizing excess anion quenching. As in the case of FIGS. 4A-4C, 5A-5C, and 6A-6C, equal diffusivity of all ions is assumed.

### DETAILED DESCRIPTION

For some active layer semiconductors, it may be more advantageous to preferentially enhance injection from, for example, the cathode with a high cation concentration near the cathode interface, and limit the anion concentration. This can preferentially enhance electron injection and create a better e/h balance to increase device quantum efficiency while minimizing the quenching and other lifetime degrading effects of excess dopant ions such as an unnecessarily high anion concentration.

Embodiments of the present invention demonstrate that doping of source layers, in which the electric field is essentially zero, produces highly effective single ion injection layers for inclusion in organic electronic devices. The source layers may be non-semiconducting, metallic or semi-metallic. Source layers include composite networks of conductive and nonconducting elements with an effectively zero internal electric field.

These zero field, single ion injection layers may comprise polymeric conjugated conductors (such as PEDOT:PSS) with additional small, mobile ionic dopants, or they may include heterogeneous metal/organic composite electrodes (such as a printed metal particle layer with organic binders, where the binder may have various functions, including but not limited to one or more of: ion complexing, electrolytic or ion-storing functions. An example light emitting polymer formulation used in the description is based on Merck/Covion Super Yellow polyphenylene vinylene, which is an organic semiconductor with a relatively low barrier to hole injection versus electron injection. For this device, the highest occupied molecular orbital (HOMO)=5.2 eV, lowest unoccupied molecular orbital (LUMO)=2.8 eV. Note that stable electrode metals of interest such as Al or Ag have work functions of ˜4.3 eV and ITO has work functions ranging from 4.3 eV to 5.2 eV depending on treatment conditions. Typical light emitting device preparation includes an oxygen plasma or UV ozone treatment to the ITO surface (UV ozone in the device examples in this invention), which are expected to result in surface potentials in the 5-5.2 eV work function range. In this case, there is little or no barrier to hole injection from an ITO anode into the SY-based semiconductor active layer while there is a substantial barrier to hole injection (˜1.5 eV) for electron injection into the SY LUMO level from a desirable, stable metal such as Al or Ag. However, there may be circumstances, such as a high LUMO and HOMO level active layer semiconductor, where hole injection is a limitation.

The external quantum efficiency of a generalized organic light-emitting device can be described in the following equation:

ηₑₓₜ=ηₚₕηᵢₙₜ=ηₚₕγφηₑₓ

where
ηₑₓₜ=external efficiency
ηₚₕ=photon out-coupling efficiency
ηᵢₙₜ=internal efficiency
γ=ratio of electrons to holes typically ≦1. There is an energy loss due this imbalance.
φ=luminescent recombination quantum efficiency of the emitter.
ηₑₓ=fraction of luminescent excitations based on spin statistics.

As can be seen in the above equation, electron/hole ratio (also referred to as ‘electron hole balance’), is a critical parameter. This parameter is affected by two device structure and materials situations: charge injection and charge transport. When charge injection barriers are low, the charge carrier currents, and therefore the electron/hole balance, can be dominated by space charge limited transport effects. These space charge effects depend on transport distance and carrier mobilities. However, in the case of interest here, high work function, stable electrode materials, typically charge injection is a more important factor. In the case of a SY-based light emitting device structure with a transparent, high work function anode and a relatively stable (>4 eV in this case) metal cathode, then, it is the electron injection which is the dominant factor for device efficiency. In this case it was expedient to use an extrinsically doped, metallic conducting polymer, PEDOT:PSS as a cation injection source. However, in a reverse configuration for a transparent cathode device, and opaque dopant injection layer the anode, such as a metal particle composite material which can accept dopants into the matrix, might be used at the anode. Furthermore, as suggested above, a hole injection limited device would benefit from cathode layer doping, either from a doped homogenous conductor material such as a doped conjugated polymer or from a heterogeneous metal composite. Metal composites are of particular interest since they are readily printable by means such as screen printing, stencil printing, flexographic printing, gravure printing, ink jet printing, aerosol spray coating, dispensing and the like.

This invention relates to doping injection layers, which are distinct from the multilayers discussed in the ‘LEP multilayer’ application. The concept here is that ions are injected into the active areas of the device through an adjacent conducting or non-semiconducting layer whereby singly-charged ions can be injected without the counter ion (counter ion is retained in the conductive layer by the electric potential of that layer which is established contact with the adjacent electrode). This would allow a situation where a higher concentration of cations could be injected into a device, under applied bias steady state, which may preferentially enhance cathode injection which is often a limiting factor for OLED devices. This is particularly true for high work function printed cathode devices. In these cases increased cathode injection can result in higher EQE through better e/h balance and longer lifetime devices. An additional supply of ions may also reduce voltage rise with lifetime through replacement of lost dopants that drift into the cathode.

Due to the effectively zero electric field in the conductive or conductive composite layer, the motion of the electrode-like charged ion is suppressed and its counter ion, in the steady-state under bias, can be injected at higher, uncompensated levels within the semiconducting active layers of the device. For example, a conducting layer, doped with a salt, such as a neutral organic ionic liquid, which is in electrical contact with the anode of the device, would preferentially inject cations from the conducting layer interface into the active layer while anion injection would be suppressed. This would create a relatively high concentration of cations which may be of particular interest when a higher amount of cations might increase the electron injection from the cathode, and therefore the quantum efficiency in an electro-injection limited device, without a corresponding increase of anion-enhanced hole injection. This is effectively independent of the ionic mobility and is therefore fundamentally different from what has been known in the industry.

To test the embodiments proposed in this invention, it was initially most expedient, due to the easy of formulation of doped printed cathode pastes and the availability of standard active layer inks, to test the counter hypothesis that including dopants in the conductive cathode for an SY device degrades the efficiency of an electron injection limited device as adding dopants to the cathode results in the injection of a higher fraction of anions into the device which negatively affects the electron/hole balance and introduces extra quenching sites. In the case of cathode doping the dopants are actually dissolved in the binder, as dopants are not soluble in the bulk metal particles that make up the conductive network within the printed composite material themselves.

An experiment was attempted based on a device structure including a patterned ITO layer on a flexible PET substrate with a gravure printed of ˜500 nm thickness doped LEP active layer (SY LEP+PEO+ionic dopant) following the basic recipe shown in below:

TABLE 1
Doped light-emitting polymer active layer formulations
Polymer SY71 Low-3 3% in 4mA
Batch Number 1544

| | Target | Actual | |
|---|---|---|---|
| | grams | grams | % error |
| SY71 Low 3 Stock Solution (3%) | 2.7698 | 2.7700 | 0.007220738 |
| PEO 300k alfa aeser solid | 0.0138 | 0.014 | 1.156069364 |
| of salt PY1A in 4-methyl | 0.1278 | 0.1294 | 1.251956182 |
| anisole | | | |
| 4-methyl anisole | 1.3890 | 1.389 | 0 |
| DBP534 (10 wt %) in 4-methyl | 0.2075 | 0.2065 | 0.477131428 |
| anisole | | | |
| DMS-T00 (10 wt %) in 4-methyl | 0.4917 | 0.4917 | 0 |
| anisole | | | |

‘4ma’ = 4-methyl anisole solvent
‘SY71” denotes a particular batch of Merck Super Yellow light emitting polymer
‘PY1A’ denotes a preformulated dopant mixture of ionic liquid butyl methyl pyrolodinium triflate sulfimide (BMPYRTfSi) and tetrabutylammonium triflate sulfimide (TBATFSi)
‘DBP534’ is a polyethylene oxide, polypropylene oxide, polydimethylsiloxane triblock copolymer with surfactant and electrolyte functionality, commercially available from Gelest
DMS-T00 is a low molecular weight siloxane surfactant that is largely volatilized during the device processing, commercially available from Gelest

A doped cathode ink for screen printing with formulation (10-243-1-ion1) with a dopant to organic binder ratio of ˜3.3% was printed and dried on top of the active light-emitting layer to form a 3-4 micron thick top electrode and complete the device stack. A parallel set of device using the control cathode mixture 10-243-1 of the same approximate thickness were also made at the same time. A certain doped cathode ink formulation, referred to as 10-243-1-ion1, disclosed only as a non-limiting illustrative example, has the following attributes:
100 g Ag Lot 10-243-1 (AG752 (Add-Vision/Conductive Compounds Ag paste recipe based on non-flaked Ag particle with ˜70% Ag load, ˜8% matrix solids, balance solvents and volatiles)
200 mg gamma butyrolactone solvent
200 mg BMPYRTFSI (ionic liquid butyl methylpyrolodinium triflate sulfimide)
70 mg TBATFSI (tetrabutyl ammonium triflatesulfimide)
   This formulation uses ˜3.3% ionic concentration to Ag binder (by weight). Measured viscosities for these formulations are 193,750 cP for the standard Ag formulation 10-243-1, and 197,500 cP for a particular ‘salty’ Ag formulation 10-243-1-ion1.

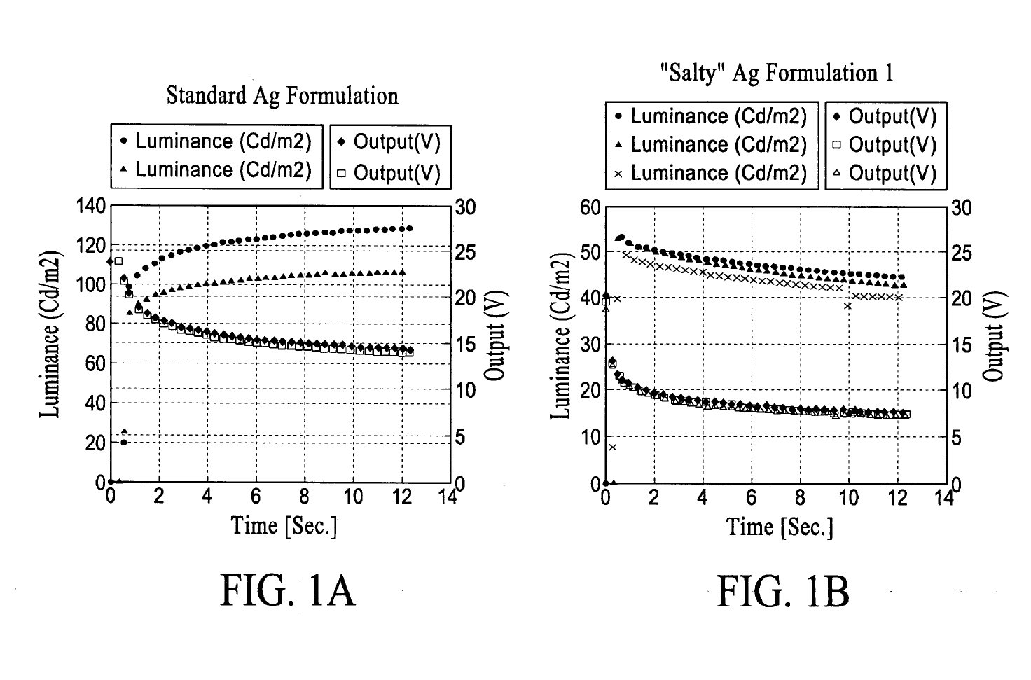

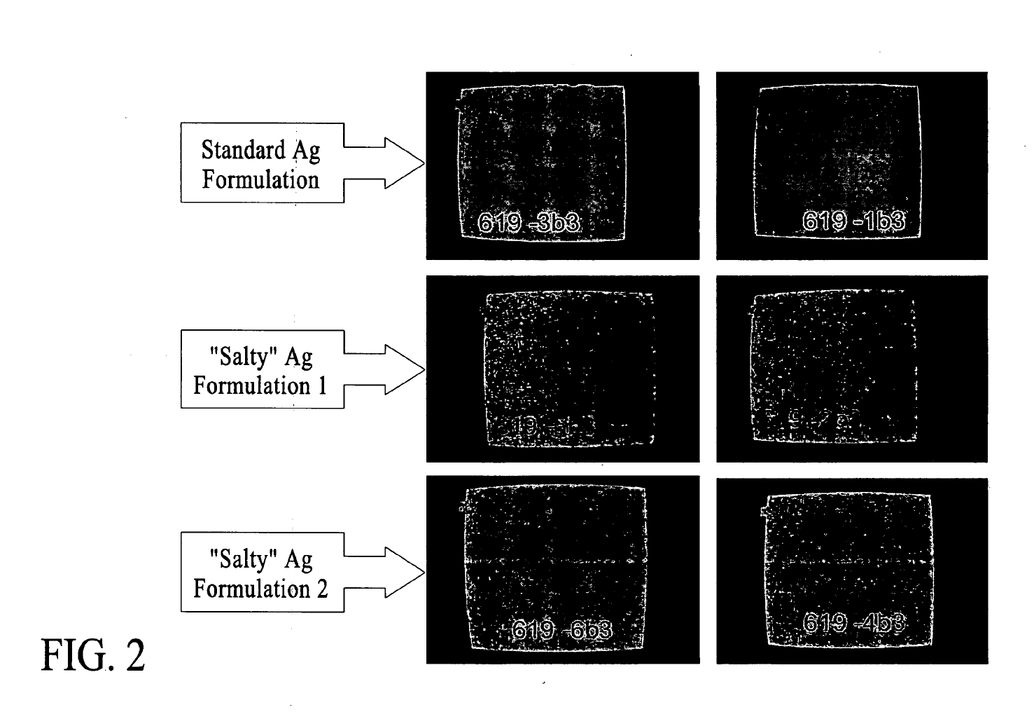

Constant current bias tests at 4 mA/cm2 were performed in nitrogen on devices with the doped cathode ‘salty’ Ag formulation along with control devices made with the control, undoped cathode formulation (i.e. the standard Ag formulation). Example data from these devices are shown in FIGS. 1A-1B. In FIGS. 1A-1B, Gravure printed LEPs were used. FIG. 1A shows results from the control device using standard Ag formulation, which needed 4.3 sec to go up to 15V. FIG. 1B shows results from a device using salty Ag formulation, which needed less than 0.29 sec to go up to 15V. The drive current was 4.0 mA. The doped cathode devices clearly show a concurrent reduction in operating voltage and efficiency relative to the controls in the initial turn-on phase of device operation. This behavior is consistent with enhanced doping of anode-adjacent device regions which would further increase hole current injection, thereby lowering the voltage required to deliver a constant current but degrading the device efficiency due to a detrimental reduction in electron/hole balance further towards low rations (hole dominated). Table 2 shows a summary of test data including time to half brightness lifetimes, peak efficiencies and voltage transient behavior as well as viscosity data for the cathodes. The viscosity data shows now substantial change in the ink viscosity (the positive increase with the dopant addition is within the error in the measurement).

TABLE 2
Experimental data summary for an example doped cathode device
Experiment 612 Summary
Gravure Printed LEP

| | Average | | Voltage at | Time to 15 V |
|---|---|---|---|---|
| Ag Type | Lifetime | QE | Max Lum | (24 V Comp) |
| 10-243-1 | 543 | 4.9 | 11.9 | 4.3 |
| Salty Formulation 1 | 3 | 1.1 | 7.9 | <.29 |
| 10-243-1-ion1 | | | | |

In this table, 10-243-1 indicates a standard Ag formulation, and, 10-243-1-ion1 indicates a particular ‘salty’ Ag formulation.

Based on the initial dramatic, negative results seen for cathode doping on printed, doped LEP devices, a second round of experiments was conducted with a reduced doping level in the cathode as it was possible that devices were being overdoped by the large total dopant amount introduced by the thick doped cathode. This included reducing the cathode doping concentration by 2× (10-243-ion2) and 10× (10-243-ion3) from the first doped cathode formulation 10-243-ion1.

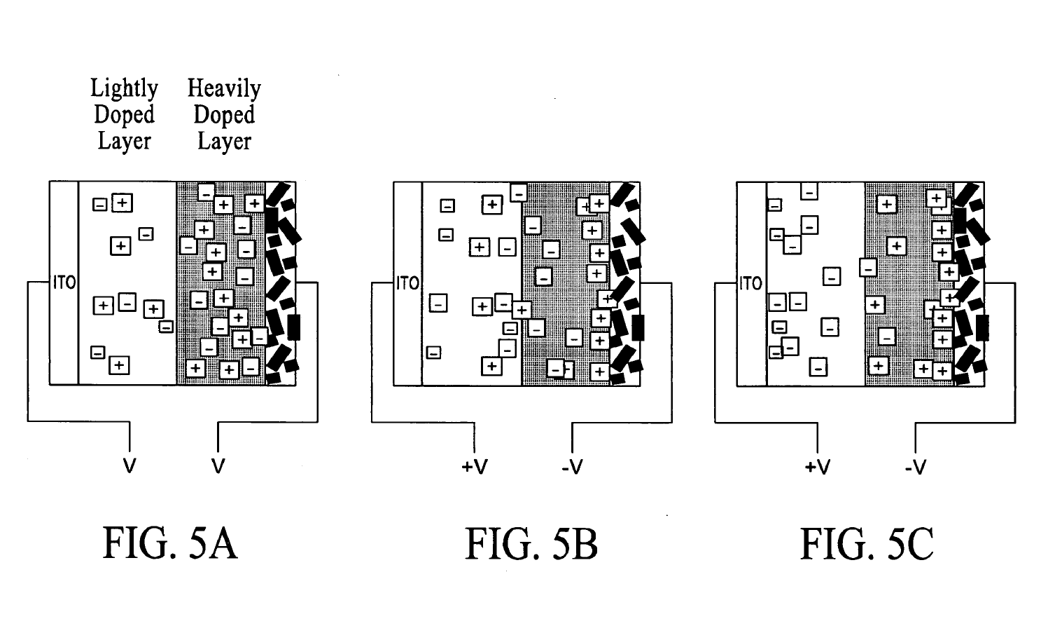

Experimental data shows that reduction of the cathode doping level did improve device performance over the first doped cathode trials (using 10-243-ion1). However efficiencies and lifetimes were still poorer than was observed for the undoped cathode controls and voltages for the more lightly doped cathodes were intermediate as compared to the devices with more heavily doped cathode and the control devices with undoped cathodes. Further reduction of the cathode doping concentration by 10× to ˜0.3% dopant/binder still showed a negative impact on the device versus the control (not shown). A generalized diagram of ionic distribution in biased, doped cathode devices is shown in FIGS. 5A-5C. These results support the following hypotheses:
(a) A higher concentration of anions reduces the anode/LEP injection barrier and increases hole injection into the device. This results in lower bias voltage under constant current operation as large hole currents are now possible at lower applied voltages. Since many OLED devices are already electron poor, and in particular printed cathode devices with a goo anode work function to active layer HOMO level (valence band), under constant current drive with a higher relative hole current, the e/h balance is pushed even more hole rich and efficiency and therefore luminance lifetime are reduced.
(b) A more advantageous situation would be to make cation-injecting anode layer which would increase the cation concentration, pushing the e/h ratio to a more balanced condition thereby increasing EQE and lifetime while reducing voltage.

These hypotheses were tested by making devices based on the LEP formulations described in the reference Kirchmeyer, S., and Reuter, K, J. Mater. Chem., 2005, 15, 2077-2088, titled, “Scientific importance, properties and growing applications of poly(3,4-ethylenedioxythiophene),” referred to as the “Kirchmeyer reference,” but which also include ionic liquid-doped PEDOT layers adjacent to the anode. Commercially-available Clevios PEDOT:PSS formulations were chosen as a suitable anode injection layer base. Use of high conductivity grades in OLEDs generally produces poor conventional OLED device lifetime results. In the printed doped LEP device structure employed here (LEC-type following the doped LEP formulations as in the Kirchmeyer reference), standard OLED grades of PEDOT:PSS such as AI 4083 have been repeatedly shown not to significantly improve device performance. This is consistent with the fact that the doped SY LEP devices employed here are note expected to benefit from attempts to increase hole injection due to the presence of suitable electrode/active layer work function match and effective doping form the active layer dopants.

In the printed device structures described in these embodiments, where we anticipate the benefit of a highly conductive dopant injection layer, we saw good results for an anode dopant injection layer based on Clevios PH500 layers doped with ionic liquid butyl methyl pyrolodinium triflate sulfimide (BMPYRTfSi) which has a highly mobile cation as demonstrated by faster device kinetics than reference tetraalkyl ammonium cations, and low tendency towards crystallization. The electrical properties of anode stacks as used in doped anode experiments here are shown in Table 3. As expected, the ITO+PEDOT:PSS stack sheet resistance is dominated by the more highly conductive ITO. The resistivities here for PH500 and PH100 are higher than values encountered in existing literature, possibly due to differences in solution filtering and thermal preparation. However, the expected trend in resistivity between the two was observed. For most of the range of doped PH500/ITO stacks some reduction in the overall parallel sheet resistance was observed due to the presence of the conductive doped PEDOT:PSS layers. It is interesting to note that the resistivity of the very highly BMP- (butylmethylpyrrolidinium triflatesulfimide) doped PH500 eventually rolls off as seen by the ITO+PEDOT:PSS,BMP stack data for Sample ID #3 where the stack resistivity now rises to approximately the same as the ITO only stack sheet resistance (OC50 ITO/Melinex ST504 PET deposited by CPFilms). In this case, the dopant content is approaching 50% of the total ‘solids’ concentration of that layer. At this point, it is possible that the effective conductivity of the PEDOT charge carrier species is breaking down due to dilution, island formation or loss of percolation. Relative dopant concentration is indicated in Table 3 by ‘#x” before the sample name which is the dopant level multiple relative to AV-L1231Y recipe dopant level. For example, PH500_BMPX2 has twice the anode layer dopant concentration that PH500_BMPX1 would have. For these devices, the reference dopant level is 4.3% of dopant total anode layer solid.

TABLE 3
Sheet resistance data from PH500-based PEDOT films
on OC50 ITO/PET at various dopant levels.

| | | Thickness (nm) | Resistivity |
|---|---|---|---|
| Sample ID | Rs (ohms/sq) | DekTak | (Ohms · cm) |
| OC50 no UVO (old ref) | 40.5 | Reported Value | |
| | | ~45.1 ohms/sq | |
| OC50 no UVO | 43.65 | | |
| OC50 UVO | 42.55 | | |
| #1: PH500 + BMP x2/ITO | 38.75 | ~60.3 | 2.33 e−4 |
| #4: PH500 + MIX x2/ITO | 39.55 | ~179 | 7.08 e−4 |
| #2: PH500 + BMP x8/ITO | 38.85 | ~58.5 | 2.27 3-4 |
| #3: PH500 + BMP x16/ITO | 42.35 | ~186 | 7.89 e−4 |
| PH500/bare PEN | 2.445 e6 | ~33 e−7* | 8.3 |
| PH500/barePEN | 0.124 e6 | ~28 e−7* | 0.34 |

*estimated from spin on glass thickness data

Device lifetime (time to half peak brightness) and peak efficiency data under constant current data from two experiments indicate a positive trend in efficiency and lifetime with ionic liquid concentration in the anode layer up to 4× the reference layer or ˜12% be weight additional dopant. These devices were similar in construction and formulation to the previously described doped cathode devices except that the cathode was undoped (as in 10-243-1 cathode formulation) and anode layers were introduced.

Further experiments were conducted with devices with anode dopant injection layers with a wider range of dopant concentrations varying from x2 to x16. Data from this experiment is shown in Table 4. This data shows a roll-off in performance with the highest doping levels. The poorer performance of the mixed dopant, which includes a lower mobility cation, shows that cation diffusivity is likely important.

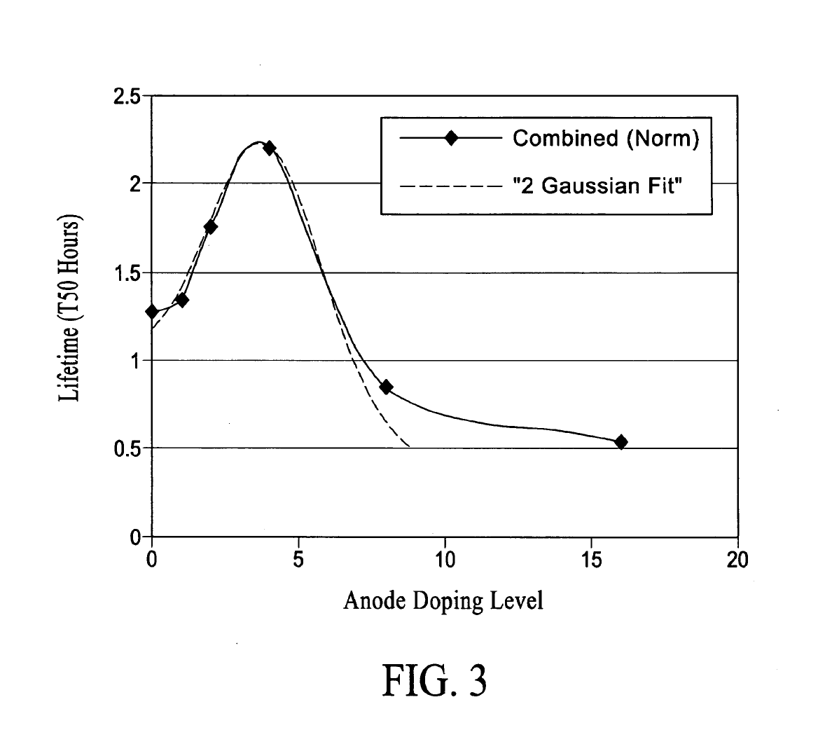

FIG. 3 shows the graphical results of combining multiple experimental data sets by normalizing each set to its control. A two exponential fit of device luminance lifetime versus doping level indicates an optimal doping level of 17% of the conducting anode total weight. Persons skilled in the art will appreciate that though exponential fit has been used here, other types of mathematical fitting mechanisms may be used too.

TABLE 4
Highest yield experimental data-set for printed
doped OLEDs with doped conductive anode layers.

| | lifetime | | | Ave. peak |
|---|---|---|---|---|
| | (hr) | Yield | Max Lum. | Cd/A |
| control | 961.0 | 100.0% | 237.5 Cd/m2 | 4.56 cd/A |
| PH500_BMPx2 | 1535.8 | 100.0% | 292.2 Cd/m2 | 5.70 cd/A |
| PH500_MIXx2* | 1112.7 | 100.0% | 259.0 Cd/m2 | 4.89 cd/A |
| PH500_BMPx8 | 820.5 | 100.0% | 224.3 Cd/m2 | 4.23 cd/A |
| PH500_BMPx16 | 519.9 | 100.0% | 175.2 Cd/m2 | 3.41 cd/A |

*‘MIX’ designates that this device was fabricated with a PEDOT: PSS dopant injection layer additionally doped with a BMPYRTfSI/TBATfSi mixture as opposed to only BMPYRTfSi dopant for ‘BMP’-designated samples

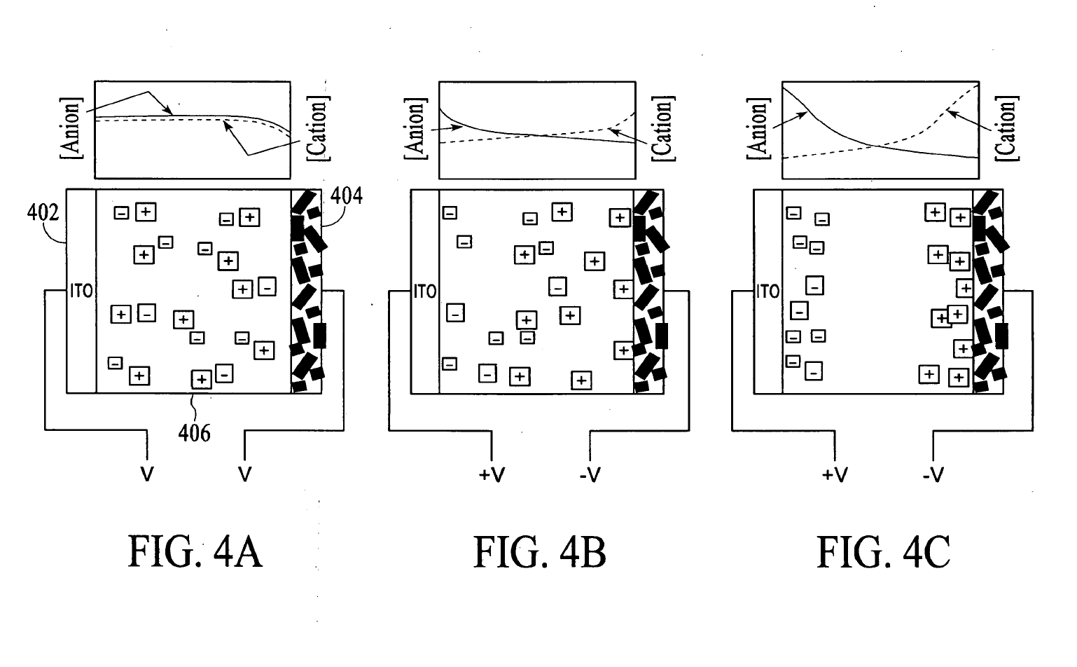

FIGS. 4A-4C show the ionic doping situation over device lifetime starting from the left (as made, unbiased), middle (initial condition after applying bias), right (after initial burn in phase—tens of hours under typical conditions) for a ‘typical’ single LEP ink composition PLED with printed cathode, where PLED is doped with proprietary material, for example compositions commercially made available by a company formerly known as Add-Vision, Inc. (AVI), based in Scotts Valley, Calif. While in the beginning a charge-neutral semi-homogeneous distribution of anions and cations are assumed, it is possible that some electrolyte may leach into cathode during cathode deposition and processing (FIG. 4A). Ion motion under bias moves cations to the cathode and the anions to the anode. Charge injection builds as ion-assisted tunneling rate rises from the electrodes into the LEP (FIG. 4B). As ion drift continues, ion concentration in the interior of the device drops which may increase radiative efficiency.

FIGS. 5A-5C show the progression of ions under bias for a doped active multilayer device in which different doping levels are introduced into subsequent active layers in the device, such as by printing. This technique can result, in the early stages of device bias, in a relatively high cation doping concentration near the cathode as compared to a homogenously doped device (as in FIGS. 4A-4C). This has some advantage over homogenously doped cathode injection-limited devices. However, this device configuration is limited by the fact that the anion and cation concentrations within the device are equal, which is non-optimal for the typical device which is intrinsically balanced in terms of electron and hole injection. This leads to higher than optimal concentrations of unnecessary counter ions within the active semiconducting layers of the device which can lead to quenching, overdoping and performance loss.

Note that there is a significant distinction between existing LEP multilayer structures, (e.g., LEP/+hole injection layer structures) and the dopant injection layers in the present application in that it is important that the ion donor layers in the embodiments of the present invention are significantly conductive. As stated previously, it is important that the dopant injection layer is conductive in that metallic conductors have an essentially zero electrical field within the bulk of the layer (in a finite carrier concentration metal including a conducting polymer, there would be some thin area of non-zero electric field) and are maintained at a particular bias. This serves to retain either cations or anions in this layer (anions in the cases of a cation-injecting dopant donor layer) while driving the counterion into the adjacent active layers. Note that this immobilization is independent of structure-induced ion mobility. The position of the electric-field retained ions in the conductive (anions, in the doped anode layer examples here) would be relatively constant over device lifetime which is different from a non-conductor with a finite electric field which would tend to drive high concentration ion drift over lifetime to the anode interface, which could be an additional source of degradation and voltage rise due to overdoping and screening effects. In the case of conducting, ion supporting donor layers, ions being driven into this layer from the active layer of the device would become immobilized and have limited impact, possibly causing some small increase in the already high charge carrier concentration in the metallic donor layer. These kind of devices often lead to earlier onset of e-injection and higher electron injection and higher electron/hole ratio compared to the homogeneously doped device of FIGS. 4A-4B.

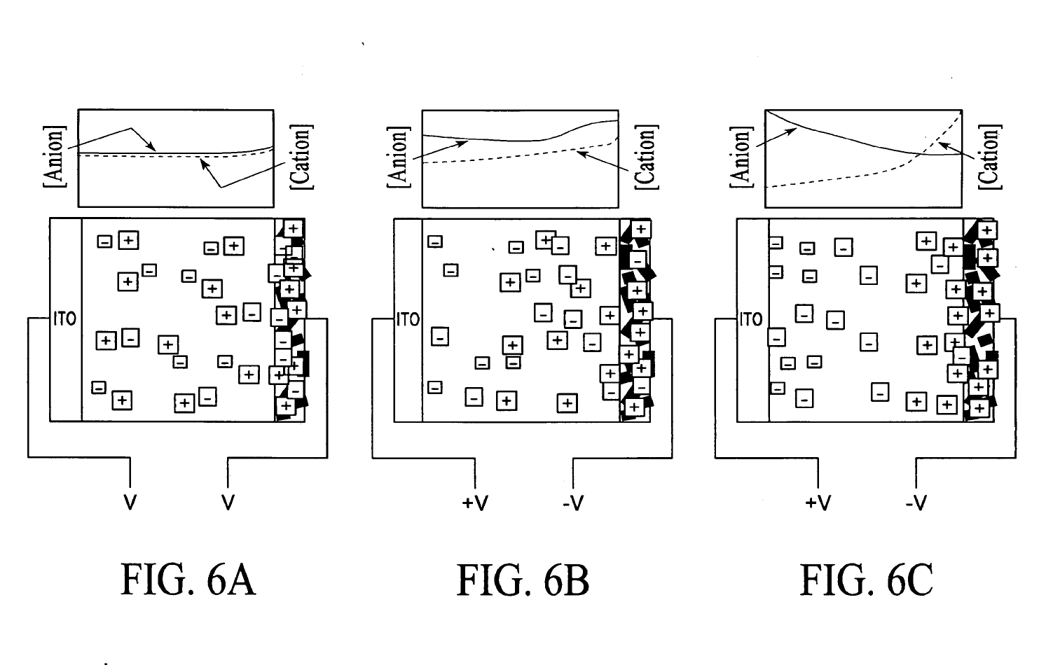

FIGS. 6A-6C show the ionic doping situation over device lifetime for a device made with a doped cathode and a homogenous LEP ink composition. FIG. 6A on the left shows the unbiased device as made; FIG. 6B in the middle shows an initial condition after applying bias; and, FIG. 6C in the right shows a condition after the initial burn in phase, for example, after tens of hours under typical conditions. The zero electric field in the cathode and the negative bias placed on the cathode under forward bias conditions would retain cations within the cathode itself and preferentially inject anions. Under steady state conditions under forward bias there would be a net higher anion concentration within the active layer of the device, which would relax after bias was removed. Specifically, FIG. 6B shows that high anion concentration in device is seen relative to non-doped cathode. Cations tend to remain in negative-biased cathode. FIG. 6C shows that anions may continue to drift from cathode due to low diffusivity in cathode and large supply volume (thicker cathode). High anion concentration may skew electron/hole balance further to hole dominance due to enhanced hole injection.

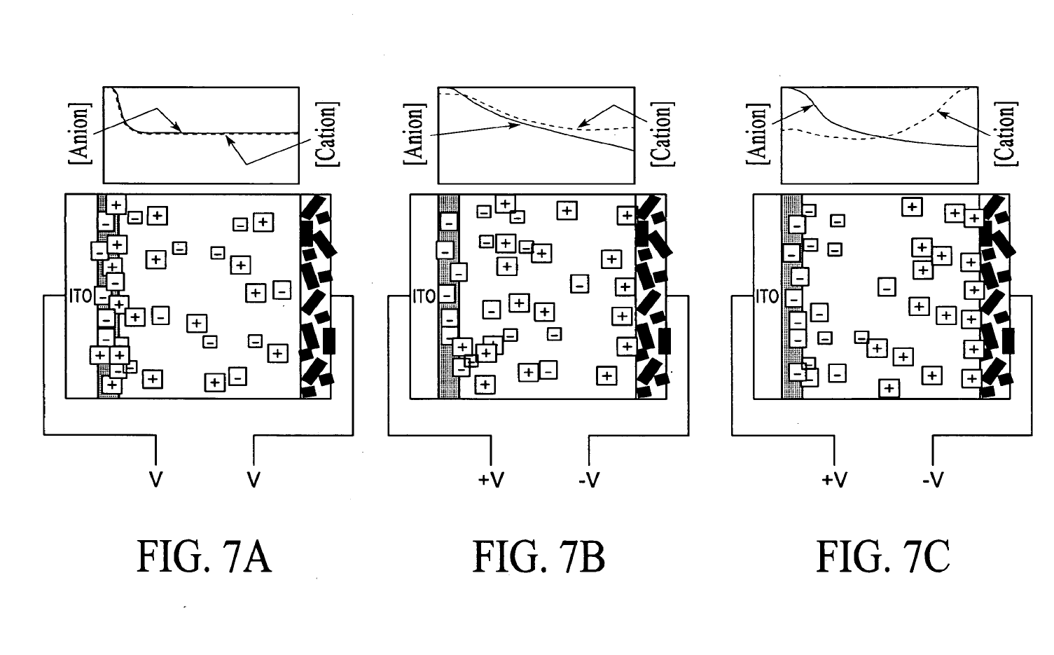

FIGS. 7A-7C show the ionic doping situation over device lifetime for a device made with a doped anode layer and a ‘typical’ single LEP ink composition AVI doped PLED with printed cathode. FIG. 7A on the left shows the unbiased device as made; FIG. 7B in the middle shows an initial condition after applying bias; and, FIG. 7C in the right shows a condition after the initial burn in phase, for example, after tens of hours under typical conditions. It may be envisioned that a possible route to increasing effecting cathode/cation doping is to have a doped anode. It is distinct from PEDOT use in a non-LEC, undoped conventional OLED/PLED in the sense that free ion motion out of the anode into the active area is undesirable and intentionally suppressed in the conventional OLED case. Specifically, FIG. 7C shows that anions may continue to drift from cathode due to low diffusivity in cathode and large supply volume (thicker cathode). High anion concentration may skew electron/hole balance further to hole dominance due to enhanced hole injection. Steady state cation concentration in LEP is higher than anion concentration.

Other possible embodiments of the present invention include metallic or semi-metallic dopant injection layers formed by a network of conductive features, such as an Ag nanowire mesh, a conductive nanotube mesh or an intentionally patterned conductor mesh. An additional component of the injection composite can be an ion supporting material and/or an electrolyte former which serves as the ion source and may also have planarizing capabilities. Such composites could be used as anode or cathode dopant injection layers and can have the advantages of being transparent (if required), flexible and potentially eliminate the need for more expensive or difficult to deposit layers such as indium tin oxide.

While certain representative embodiments and details have been shown for purposes of illustrating the invention, it will be apparent to those skilled in the art that various changes in the methods and apparatus disclosed herein may be made without departing from the scope of the invention which is defined in the appended claims. Additionally, the commercial names of materials mentioned in the description are used to facilitate the reader's understanding, without any suggestion that the invention is restricted to only certain device configurations and materials mentioned herein.

1. An isopotential source layer for an electronic device, wherein the source layer provides ions of charge to be preferentially injected into an active layer of the electronic device, wherein a charge of the injected ions has the same sign as the sign of a relative bias applied to the isopotential source layer.

2. An electronic device containing the isopotential source layer of claim 1, wherein the source layer comprises a composite ionic dopant injection layer having at least one component that has a relatively high diffusivity for ions.

3. The device of claim 2, wherein the composite ionic dopant injection layer comprises metallic conductive particles and an ion supporting matrix.

4. The device of claim 2, wherein the composite ionic dopant injection layer comprises a continuous metallic conductive network and an ion supporting matrix.

5. The device of claim 4, wherein the metallic network comprises metallic nanowires or conductive nanotubes.

6. The device of claim 3, wherein the ion supporting matrix comprises a conductive polymer.

7. The device of any of claim 2, wherein the device comprises a transparent anode, a conducting polymer layer in contact with the transparent anode with additional mobile ion dopants adjacent to the active layer.

8. The device of any of claim 2, wherein the device comprises a transparent cathode and a doped anode, the doped anode which being a composite of an electrically continuous network of metallic elements and an ion supporting matrix.
